(19) United States
(12) Patent Application Publication
(10) Pub. No.: US 2025/0070101 A1
(43) Pub. Date: Feb. 27, 2025

(54) DUAL SWITCHING POWER DEVICE

(71) Applicant: Texas Instruments Incorporated, Dallas, TX (US)

(72) Inventors: Makoto Shibuya, Tokyo (JP); Woochan Kim, San Jose, CA (US); Kwang-Soo Kim, Sunnyvale, CA (US)

(21) Appl. No.: 18/455,558

(22) Filed: Aug. 24, 2023

(51) Int. Cl. H01L 25/16; H01L 23/00; H01L 23/495; H01L 23/52; H01L 25/00; H05K 1/18

(52) U.S. Cl. CPC H01L 25/16; H01L 23/49537; H01L 23/49575; H01L 23/52; H01L 24/37; H01L 24/40; H01L 24/83; H01L 24/84; H01L 24/92; H01L 25/50; H05K 1/181; H01L 23/49562; H01L 24/32; H01L 24/48; H01L 24/73; H01L 2224/32245; H01L 2224/37011; H01L 2224/37147; H01L 2224/4005; H01L 2224/40137; H01L 2224/40245; H01L 2224/48091; H01L 2224/48141; H01L 2224/48245; H01L 2224/48465; H01L 2224/73221; H01L 2224/73263; H01L 2224/73265; H01L 2224/83192; H01L 2224/83815; H01L 2224/8402; H01L 2224/84815; H01L 2224/92157; H01L 2224/92246; H01L 2224/92247; H01L 2924/13091; H01L 2924/1426; H05K 2201/10378

(57) ABSTRACT

An electronic device includes a package structure, conductive leads, first and second semiconductor dies, and a metal clip, The package structure has opposite longitudinal ends, opposite lateral sides, a middle portion midway between the longitudinal ends, a first portion that extends between the middle portion and one longitudinal end, and a second portion that extends between the middle portion and the other longitudinal end. The metal clip extends in the package structure from the first portion to the second portion through the middle portion and electrically couples the first electronic component of the first semiconductor die to the second electronic component of the second semiconductor die.

### BACKGROUND

Power systems are used in a variety of applications, such as automotive components, industrial systems, computing devices, smart phones, etc. As advanced systems become smaller, power converter designs require smaller footprints, ease of use, and lower cost. All in one power modules are desirable for miniaturization, but considering the cost and flexibility of design, it may be better in some cases to design the power circuit with discrete products, and component product offerings must provide design flexibility and device capability to accommodate different design approaches. Many AC-DC or DC-AC circuits need at least two switching power devices, driver circuitry and passive components in half bridge circuits.

### SUMMARY

In one aspect, an electronic device includes a package structure with opposite longitudinal ends and opposite lateral sides, conductive leads partially exposed outside the lateral sides of the package structure, first and second semiconductor dies, and a metal clip. The package structure has a middle portion midway between the longitudinal ends, a first portion that extends between the middle portion and one longitudinal end, and a second portion that extends between the middle portion and the other longitudinal end. The metal clip extends in the package structure from the first portion to the second portion through the middle portion and electrically couples a first electronic component of the first semiconductor die to a second electronic component of the second semiconductor die.

In another aspect, an electronic device includes a package structure having opposite longitudinal ends spaced apart from one another along a first direction, and opposite lateral sides spaced apart from one another along a second direction that is orthogonal to the first direction, conductive leads partially exposed outside the respective lateral sides of the package structure, a semiconductor die having an electronic component, and a metal clip electrically coupled to the electronic component and exposed outside a first one of the longitudinal ends.

In another aspect, a system includes a circuit board and an electronic device attached to the circuit board. The electronic device includes a package structure with opposite longitudinal ends and opposite lateral sides, conductive leads partially exposed outside the lateral sides of the package structure and soldered to conductive features of the circuit board, first and second semiconductor dies, and a metal clip. The package structure has a middle portion midway between the longitudinal ends, a first portion that extends between the middle portion and one longitudinal end, and a second portion that extends between the middle portion and the other longitudinal end. The metal clip extends in the package structure from the first portion to the second portion through the middle portion and electrically couples a first electronic component of the first semiconductor die to a second electronic component of the second semiconductor die.

In a further aspect, a method of fabricating an electronic device includes: attaching a first semiconductor die to a first die attach pad in a first row of a column of a lead frame panel array; attaching a second semiconductor die to a second die attach pad in an adjacent second row of the column of the lead frame panel array; attaching a metal clip to the first and second semiconductor dies with the metal clip extending in the first and second rows; forming a package structure that extends along the column and encloses the first and second semiconductor dies and the metal clip; trimming conductive leads along longitudinal sides of the column of the lead frame panel array; and separating the electronic device from the lead frame panel array.

### BRIEF DESCRIPTION OF THE DRAWINGS

FIG. 1 is a top perspective view of an electronic device including a half bridge circuit with high and low side transistors in respective portions and a switching node clip extending through a middle portion.

FIG. 1A is a top plan view of the electronic device of FIG. 1.

FIG. 1B is a top perspective view of the electronic device of FIGS. 1 and 1A.

FIG. 1C is a bottom perspective view of the electronic device of FIGS. 1-1B.

FIG. 1D is a top plan view of a power conversion system with the electronic device of FIGS. 1-1C attached to a circuit board.

FIG. 1E is a simplified schematic diagram of the power conversion system of FIG. 1D.

FIG. 2 is a flow diagram of a method of fabricating an electronic device.

FIGS. 3-14 are partial top plan views of the electronic device of FIGS. 1-1C undergoing fabrication processing in a column and adjacent first and second rows of a lead frame panel array.

FIG. 14A is a partial top plan view of two adjacent single transistor electronic devices fabricated in another column of the lead frame panel array.

FIG. 14B is a partial top perspective view of two adjacent columns of the lead frame panel array after column direction lead trimming and prior to row direction package separation.

FIG. 14C is a partial top perspective view of portions of the two adjacent columns of the lead frame panel array after selective row direction package separation.

FIG. 14D is a partial top plan view of two further adjacent electronic devices in another column of the lead frame panel array after selective row direction package separation that cuts through a column molded package structure and a portion of a clip.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc. may be referred to herein as first, second, third, etc., such as first and second terminals, first, second, and third, wells, etc., for case of description in connection with a particular drawing, where such are not to be construed as limiting with respect to the claims.

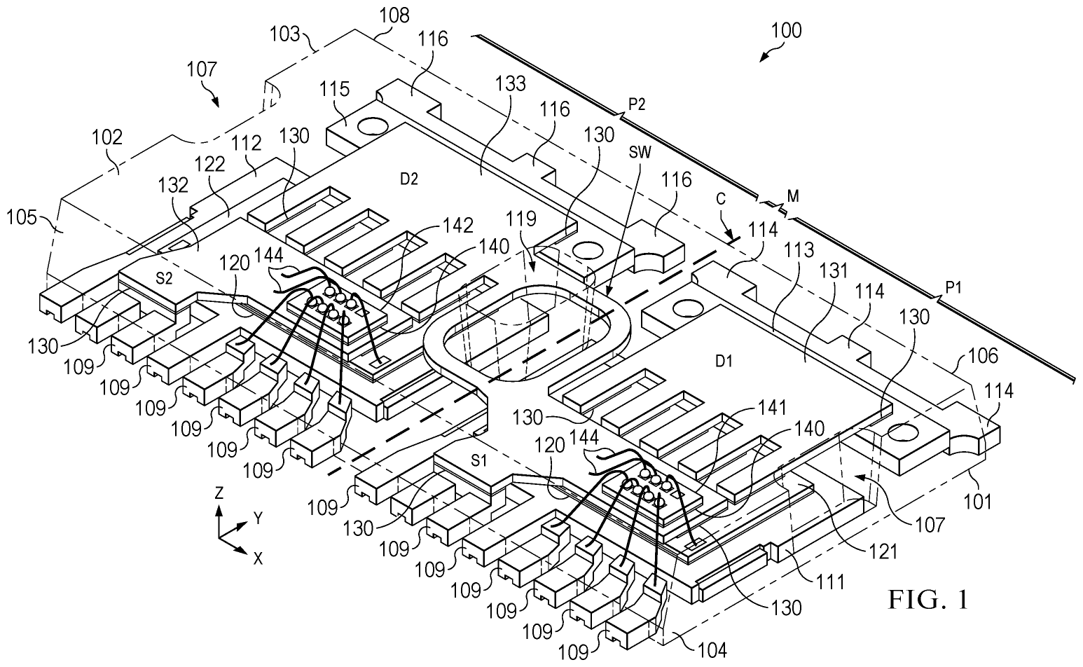

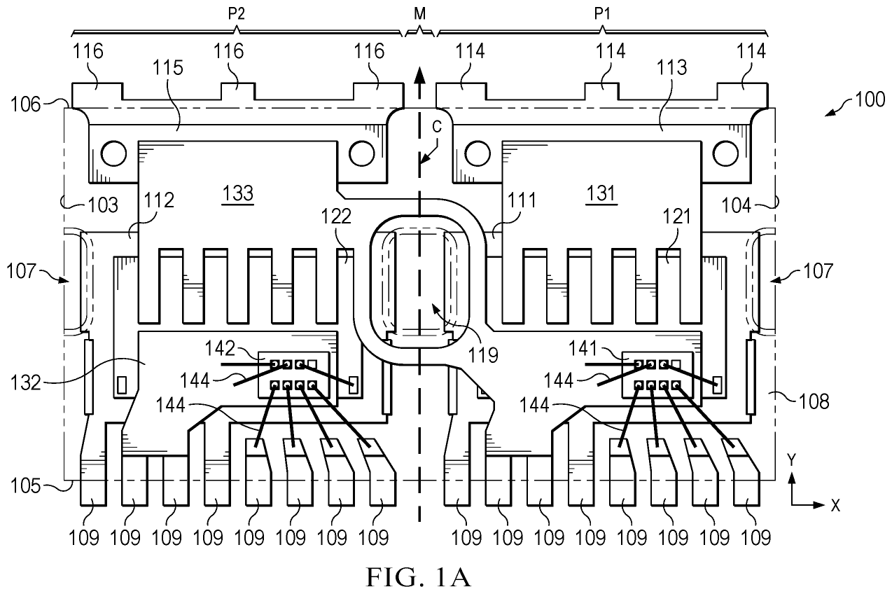

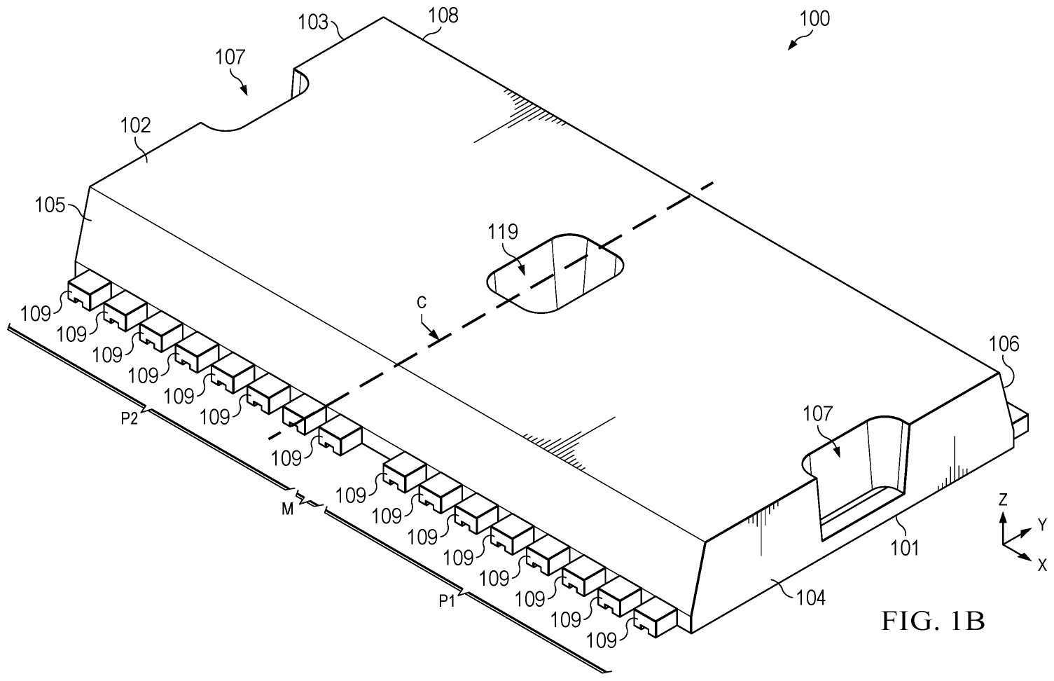

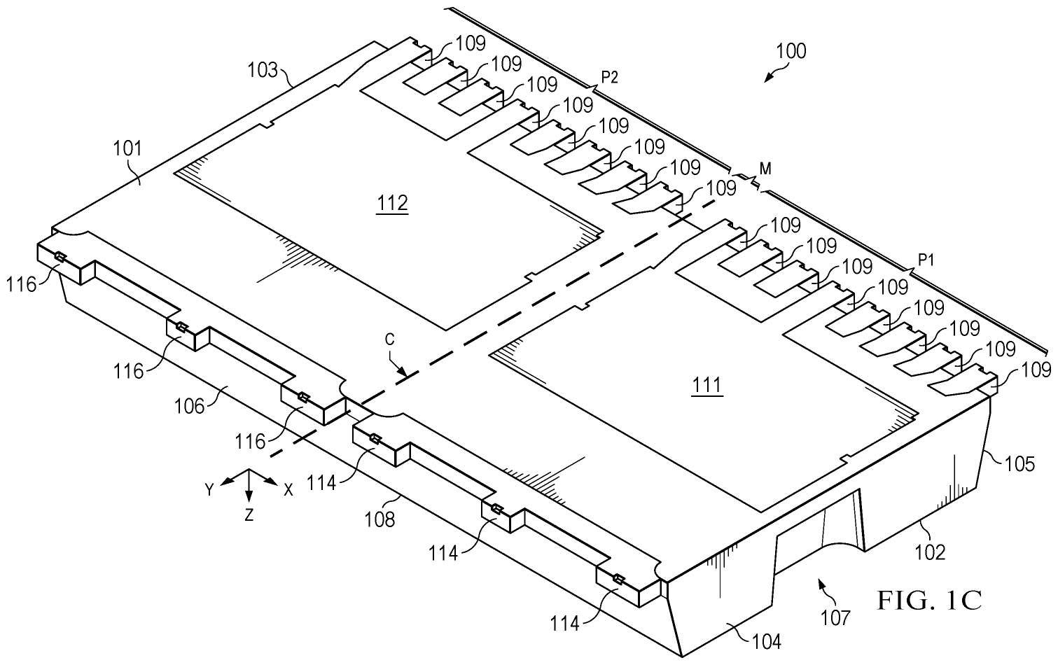

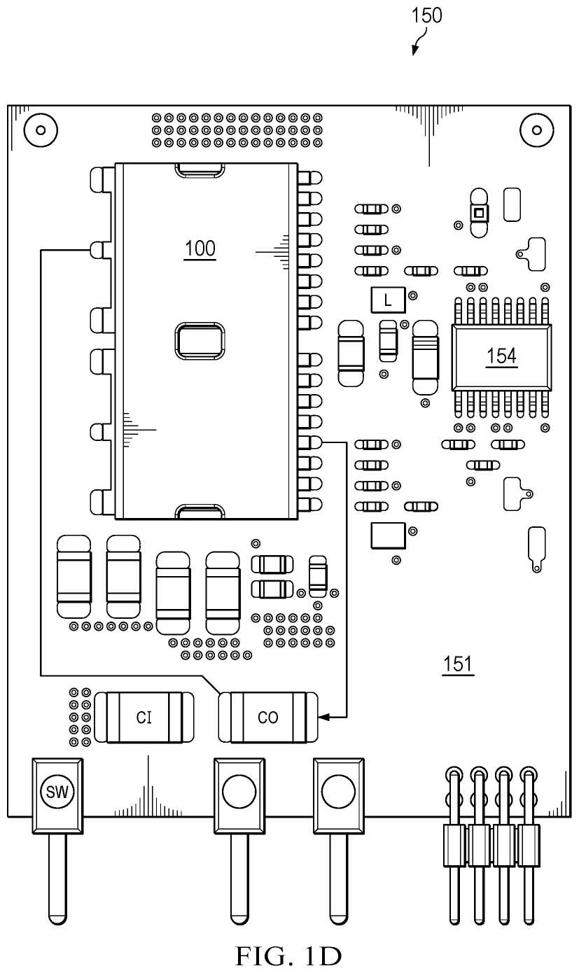

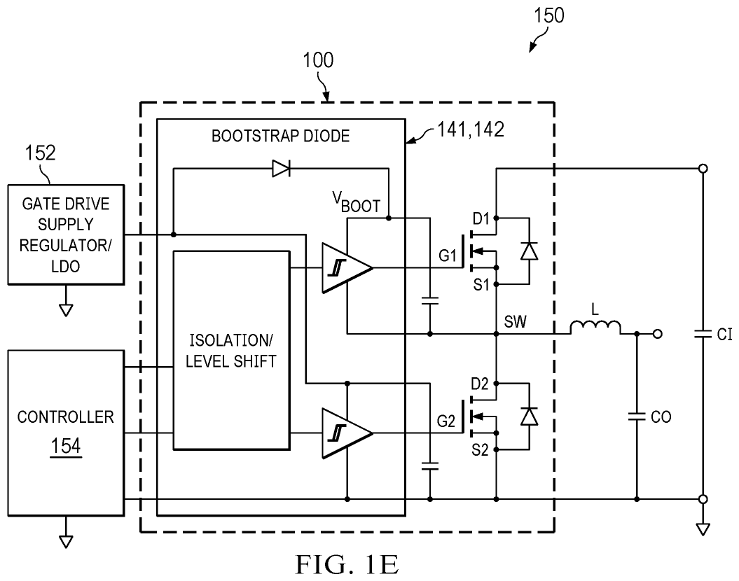

Referring initially to FIGS. 1-1C, FIG. 1 shows an electronic device 100 that includes a half bridge circuit with high and low side transistors in respective portions and a switching node clip extending through a middle portion in a transistor outline (TO) leadless package arrangement (TOLL). FIG. 1A shows a top view, FIG. 1B shows a top perspective view, and FIG. 1C shows a bottom perspective view of the electronic device 100. The electronic device 100 provides modular power stage functionality with two driver and transistor units connected by a metal switching node clip to implement a half bridge module that can be used in a power system.

FIGS. 1-1C show the electronic device 100 in an example position in a three-dimensional space with a first direction X, a perpendicular (orthogonal) second direction Y (FIG. 1A), and a third direction Z that is perpendicular (orthogonal) to the respective first and second directions X and Y. Structures or features along any two of these directions are orthogonal to one another. As shown in FIGS. 1, 1B, and 1C, the electronic device 100 has opposite first and second (e.g., bottom and top) sides 101 and 102, respectively, which are spaced apart from one another along the third direction Z in the illustrated orientation. The electronic device 100 has opposite third and fourth sides 103 and 104, also referred to herein as longitudinal ends 103 and 104, which are spaced apart from one another along the first direction X and extend along the second direction Y. The electronic device 100 also includes respective fifth and sixth sides 105 and 106, also referred to as opposite lateral sides 105 and 106, which are spaced apart from one another along the second direction Y in the illustrated position.

The electronic device 100 has a molded package structure 108 that forms parts of the device sides 101-106. The package structure 108 has indents 107 that extend into the longitudinal ends 103 and 104. In the illustrated example, the respective sides 101-106 are generally planar, the bottom and top sides 101 and 102 extend in respective X-Y planes, and the longitudinal ends 103 and 104 extend in respective Y-Z planes of the second and third directions Y and Z. The sides 101-106 in one example have substantially planar outer surfaces. In other examples, one or more of the sides 101-106 have curves, angled features, or other non-planar surface features. The package structure 108 has a middle portion M midway approximately between the longitudinal ends 103 and 104 along a centerline C. The package structure 108 also has a first portion P1 that extends between the middle portion M and one of the longitudinal ends 104, and a second portion P2 that extends between the middle portion M and the other one of the longitudinal ends 103.

The electronic device 100 also includes conductive leads 109 along the lateral fifth side 105, a first conductive metal die attach pad 111 in the first portion P1, a second conductive metal die attach pad 112 in the second portion P2, a first transistor drain lead frame portion 113 with conductive leads 114 along the lateral sixth side 106 in the first portion P1, and a second transistor drain lead frame portion 115 with conductive leads 116 along the sixth side 106 in the second portion P2. The leads 109, 114, and 116, as well as the die attach pads 111 and 112 and the lead frame portions 113 and 115 in one example are or include copper or other suitable conductive metal. The conductive leads 109 are partially exposed outside the lateral side 105 and the conductive leads 114 and 116 are partially exposed outside the lateral side 106 of the package structure 108. As further shown in FIG. 1C, moreover, the bottoms of the conductive leads 109, 114, and 116, the bottom sides of the conductive metal die attach pads 111 and 112, and the bottom sides of the and the lead frame portions 113 and 115, are exposed outside the package structure 108 along the first or bottom side 101 of the electronic device 100.

In use in a host system (e.g., FIG. 1D below), the bottoms of the conductive leads 109, 114, and 116 can be soldered to corresponding conductive metal features (e.g., pads) of a host circuit board to provide electrical connections to circuitry of the electronic device 100, and one or more of the bottom sides of the conductive metal die attach pads 111 and 112, and the bottom sides of the lead frame portions 113 and 115 can also be soldered to a host circuit board. In addition, the sides of one or more of the conductive leads 109, 114, and/or 116 can accommodate adherence to solder, for example, to facilitate solder wetting and proper solder connections during attachment of the electronic device 100 to a host circuit board.

As shown in FIGS. 1-1B, the example package structure 108 has an opening 119 that extends into the middle portion M along the third direction Z. In the illustrated example, portions of the first and second die attach pads 111 and 112 are exposed in the opening 119 of the package structure 108.

As best shown in FIGS. 1 and 1A, the electronic device 100 includes a first semiconductor die 121 attached by solder 120 (FIG. 1) to the first conductive metal die attach pad 111 in the first portion P1, as well as a second semiconductor die 122 attached by solder 120 (FIG. 1) to the second conductive metal die attach pad 112 in the second portion P2. In this example, the first and second semiconductor dies 121 and 122 of FIGS. 1 and 1A have respective first and second transistor electronic components (e.g., field effect transistors Q1 and Q2 schematically illustrated in FIG. 1E below). The transistor Q1 in FIG. 1E (e.g., of the of the first semiconductor die 121 in FIGS. 1 and 1A) is configured as a high side transistor and a half bridge circuit that includes a first drain D1 and a first source S1 with schematic connections illustrated in the first portion P1 FIG. 1, as well as a first gate G1 (FIG. 1E). The second transistor Q2 in this example is configured as a low side transistor of the half bridge circuit that has a second drain D2, a second source S1, and a second gate G2. The first and second semiconductor dies 121 and 122 can be any suitable semiconductor material, such as silicon, gallium nitride, etc.

As further shown in FIGS. 1 and 1A, the electronic device 100 also includes conductive metal clips 131-133, which can be or include copper or other suitable conductive metal material. The illustrated example includes a first metal clip 131 attached by solder 130 to form a mechanical and electrical connection between the first transistor drain lead frame portion 113 and conductive drain terminals on the top side of the first semiconductor die 121 to provide a first drain connection D1 to the conductive leads 114 along the lateral sixth side 106 of the electronic device 100. A second metal clip 132 in this example is attached by solder 130 to form a mechanical and electrical connection between a first pair of the conductive leads 109 of the second portion P2 and conductive source terminals on the top side of the second semiconductor die 122 to provide the second source connection S2 along the lateral fifth side 105 of the electronic device 100. In another implementation, bond wire connections (not shown) can be used to provide the electrical interconnections of the first drain D1 and the second source S2, and the associated first and second metal clips 131 and/or 132 can be omitted.

The electronic device 100 also includes a third metal clip 133 enclosed by the package structure 108. The package structure 108 also encloses the semiconductor dies 121 and 122 and inner portions of the conductive leads 109, 114, 116 and the die attach pads 111 and 112. The metal clip 133, and any included clips 131 and/or 132, can be any suitable conductive metal material, such as copper or material that includes copper or other conductive metal. The third metal clip 133 extends in the package structure 108 from the first portion P1 to the second portion P1 through the middle portion M and electrically couples the first electronic component Q1 of the first semiconductor die 121 to the second electronic component Q2 of the second semiconductor die 122.

The metal clip 133 extends in the package structure 108 from the first portion P1 to the second portion P1 through the middle portion M and electrically couples the first electronic component Q1 of the first semiconductor die 121 to the second electronic component Q2 of the second semiconductor die 122. As shown in FIGS. 1 and 1A, the metal clip 133 in the illustrated example provides a switching node SW connected to the first source S1 of the first semiconductor die 121 in the first portion P1 and to the second drain D2 of the second semiconductor die 122 in the second portion P2. The metal clip 133 in this example also provides mechanical and electrical connection of the first source S1 to two of the conductive leads 109 along the fifth side 105 in the first portion P1, as well as mechanical electrical connection of the second drain D2 to the second transistor drain lead frame portion 115 and the conductive leads 116 along the sixth side 106 in the second portion P2.

The illustrated metal clip 133 encircles the opening 119 and has two branch portions that separately extend through the middle portion M around two opposite sides of the opening 119. In another example, the metal clip 133 need not laterally encircle the opening 119 and can have one or more portions that extend through the middle portion M on only one side of the opening 119. In a further example, the metal clip 133 can have more than one portions that extend through the middle portion M on either or both lateral sides of the opening 119. In another example, the opening 119 of the package structure 108 can be omitted.

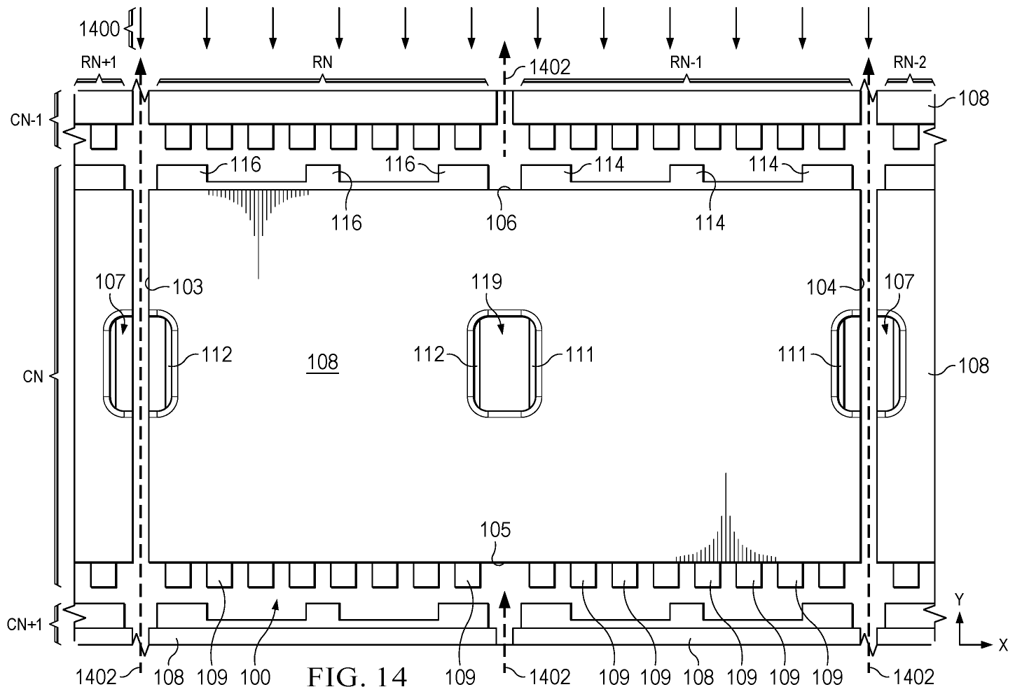

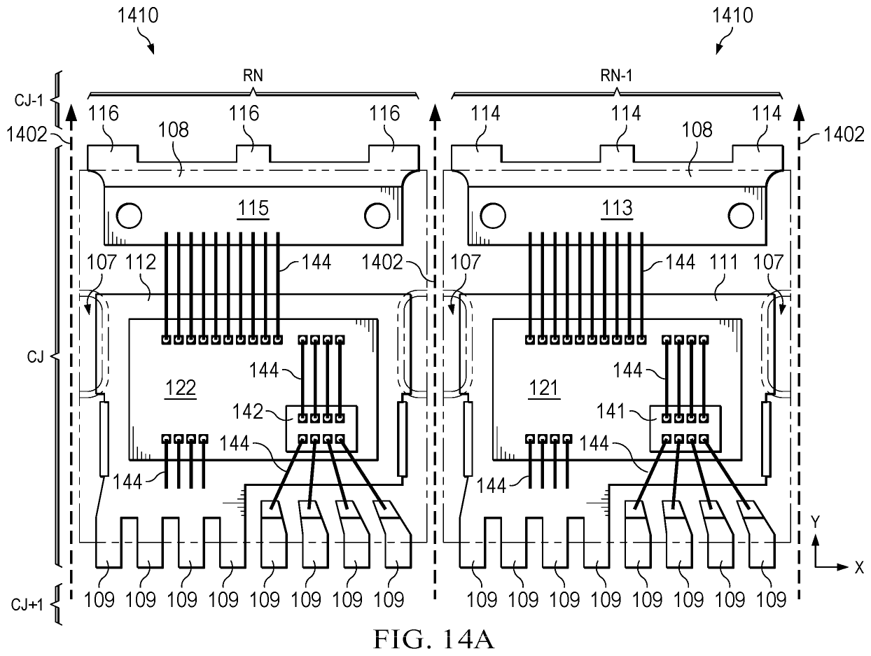

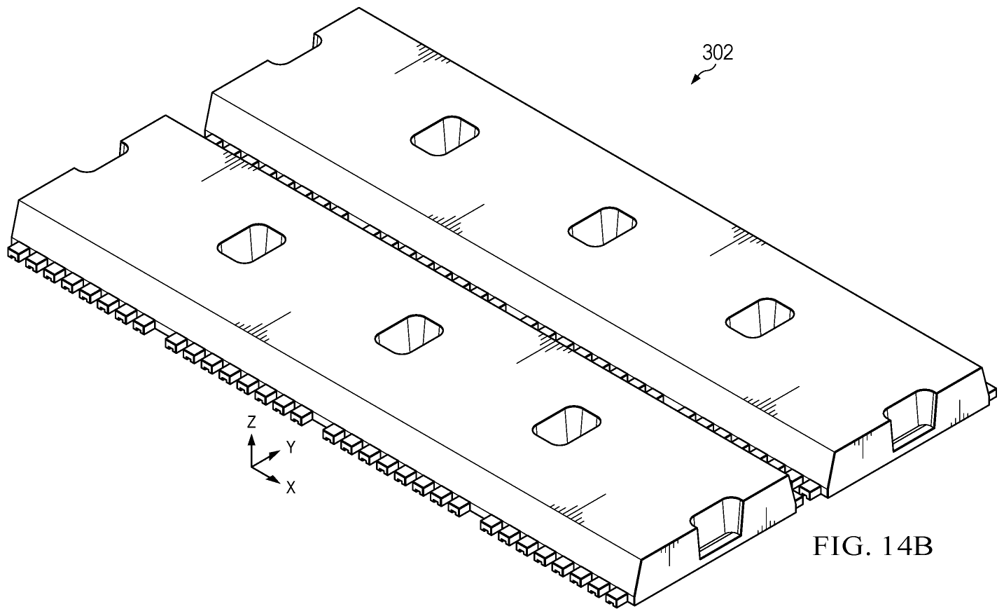

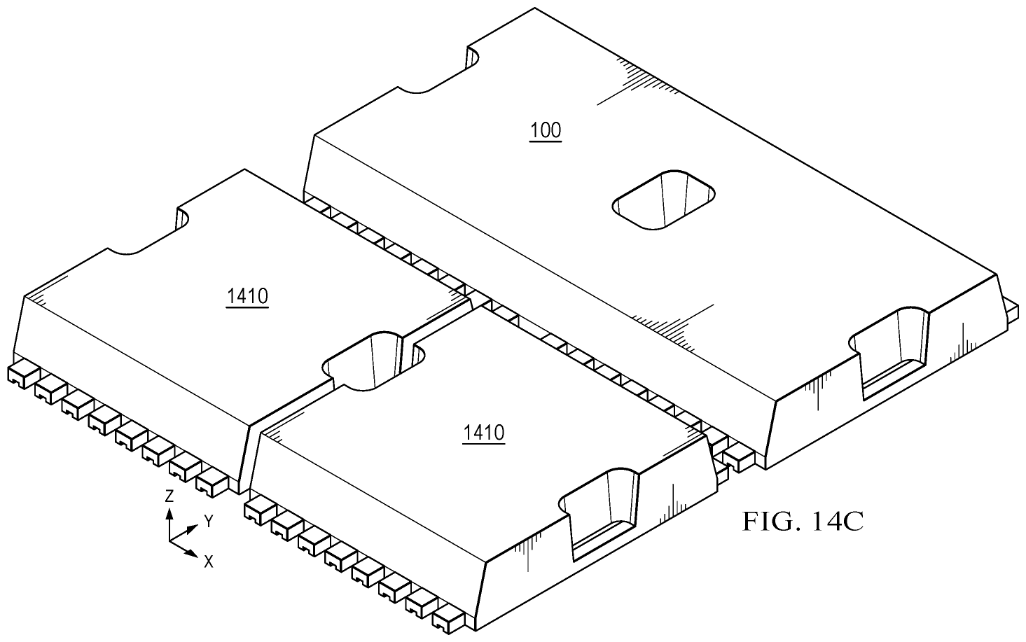

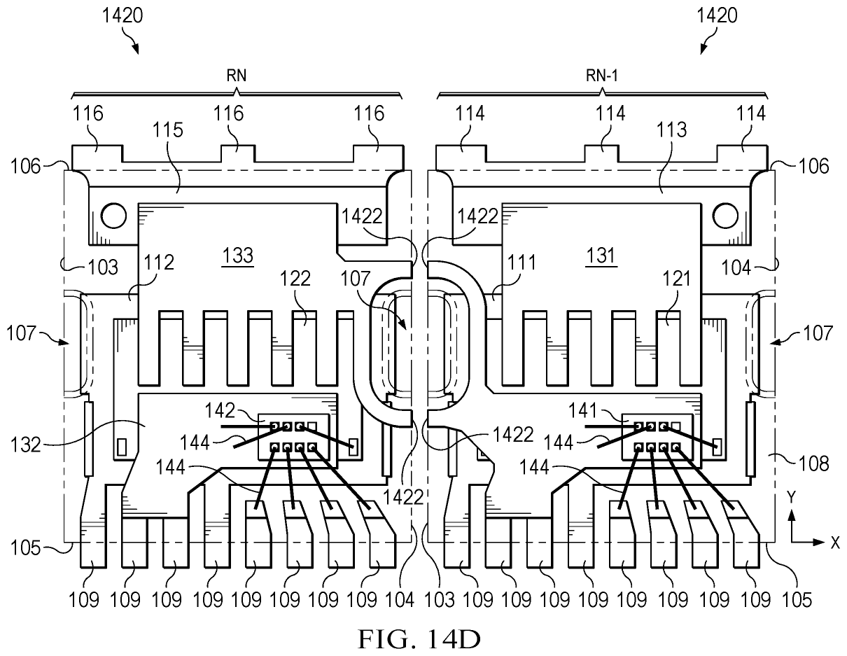

The electronic device 100 in FIGS. 1-1C provides an integrated half bridge transistor circuit that can be used as a module in constructing a variety of different power converter architectures, providing a compact module that can be integrated with other external components, for example, on a host printed circuit board, as illustrated and described further below in connection with FIGS. 1D and 1E. It is further noted that the illustrated structure can be modified by cutting along the centerline C to provide to separate single transistor modules that can be used as components in a power converter or other transistor circuit, for example, as illustrated and described further below in connection with FIG. 14D.

The electronic device 100 in the illustrated example also includes onboard driver circuitry, with a first driver die 141 attached by an adhesive 140 (e.g., epoxy) to a portion of the top side of the metal clip 133 in the first portion P1, as well as a second driver die 142 attached by adhesive 140 to a portion of the top side of the second metal clip 132. The electronic device 100 also includes bond wires 144 that form electrical circuit connections between the respective driver dies 141 and 142 and the transistor electronic components of the semiconductor dies 121 and 122, as well as connections to respective ones of the conductive leads 109, for example, to allow connection of the transistor switching control signals from other components or systems of a host printed circuit board.

The metal clip 133 in the electronic device 100 advantageously provides interconnection of the high and low side circuitry in the respective first and second portions P1 and P2 by a conductive metal switching node structure that can carry high currents associated with power conversion circuitry. In this regard, the metal clip 133 can be constructed of copper or other suitable metal having a thickness that is greater than the thickness of the structures 109 and 111-116 of a starting lead frame, to advantageously utilize existing lead frame structures (e.g., having a thickness of approximately 0.5 mm), potentially with multiple leads 109, 114, and/or 116 for high current circuit nodes, while using the higher current carrying capability of the metal clip 133 to accommodate switching node currents in a power converter. The electronic device 100 and variants thereof also facilitate sharing of tools and machinery with other power conversion system components and modules in constructing half bridge in full bridge power conversion systems and other circuit topologies.

The illustrated example, moreover, provides a modular half bridge module using a transistor outline leadless (TOLL) structure for compact system designs, while providing high switching node current capability compared with standard printed circuit board copper traces to interconnect a switching node with an inductor or other power converter components. The TOLL package of the illustrated example facilitates use in high current applications, such as automotive systems, industrial systems, computers, smart phones, battery chargers, etc., and can facilitate high power applications with good efficiency, low electromagnetic interference (EMI) performance and/or good thermal performance in compact high circuit density applications.

In addition, the metal clip 133 and the high current capability of the various circuit nodes of the electronic device 100 advantageously facilitate low parasitic inductance, low impedance, and improved thermal performance in power conversion and other system applications, and the modular construction of the electronic device 100 can help reduce component count, cost, and circuit area in a surface mount technology (SMT) implementation of a host printed circuit board and allow case of manufacturing and low cost for end-users

Referring also to FIGS. 1D and 1E, FIG. 1D shows a top view of a power conversion system 150 with the electronic device 100 attached to a circuit board 151, and FIG. 1E shows a simplified schematic diagram of the power conversion system 150. In this example, the conductive leads 109, 114, and 116 of the electronic device 100 are soldered to corresponding conductive pads on the top side of the circuit board 151 along with other components on the top side of the circuit board 151 using a conventional surface mount technology process.

The example power conversion circuit in FIG. 1E includes a gate drive supply regulator 152, such as a low dropout (LDO) circuit formed by various components on the circuit board 151 of FIG. 1D, as well as a controller chip 154 implemented as another electronic device soldered to the circuit board 151 as shown in FIG. 1D. The circuit board 151 also includes various passive components, such as input and output capacitors CI and CO, respectively, a switching inductor L connected between an output node and the switching node SW, and various terminals to allow connection of power and control signals to the circuit board 151.

The electronic device 100 in this example includes the onboard driver circuit dies 141 and 142 that can implement gate driver circuits, a bootstrapped diode, isolation and level shifting circuitry, etc. of the buck converter circuit shown in FIG. 1E. As noted above, the provision of separate driver dies 141 and 142 in the respective first and second portions P1 and P2 of the electronic device 100 facilitate selective cutting along the centerline C in order to selectively provide individual single transistor modules that can (but need not) be interconnected and a half bridge circuit. In another implementation, a single driver die (not shown) can be provided in the half bridge electronic device 100 in either the first or second portions P1, P2, or such a single driver die can extend at least partially in the middle portion M or in any two or more of the illustrated portions P1, P2, M.

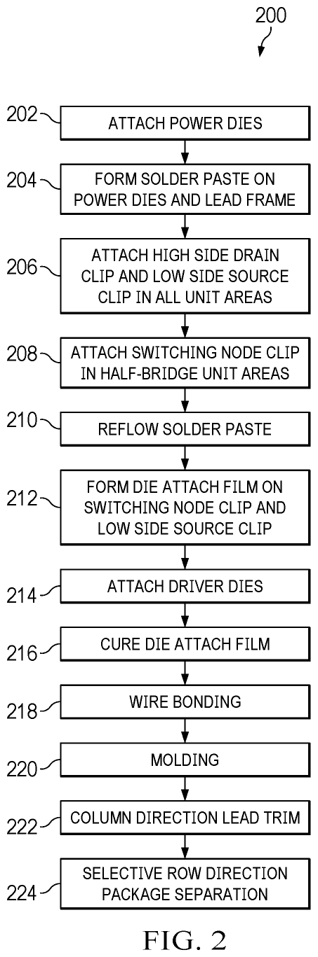

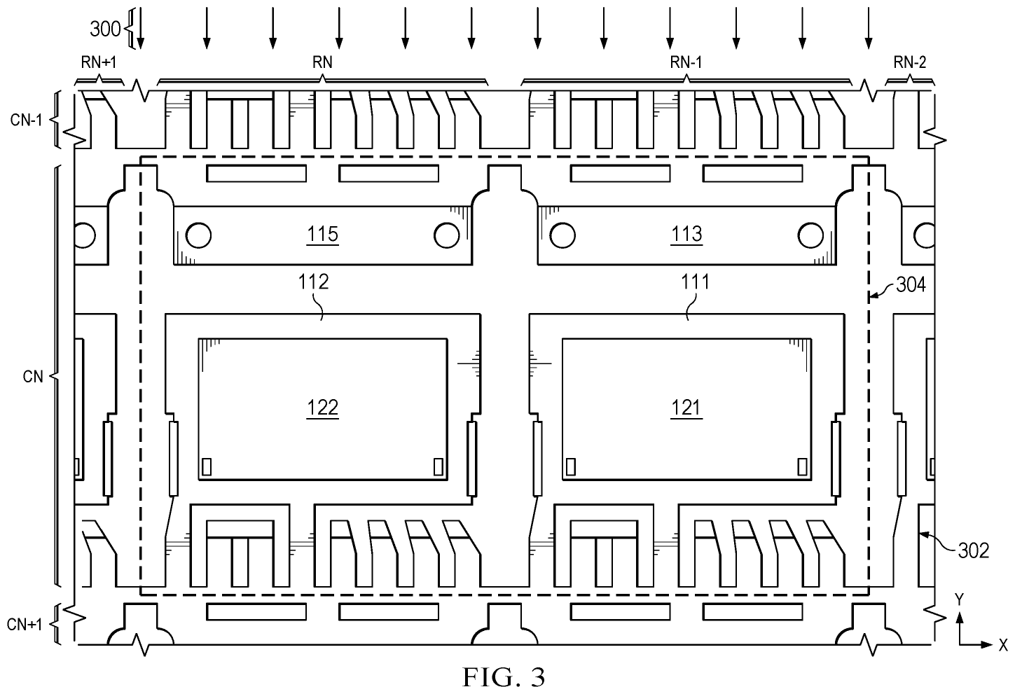

Referring now to FIGS. 2-14, FIG. 2 shows a method 200 of fabricating an electronic device, and FIGS. 3-14 show the electronic device 100 undergoing fabrication processing in a first column and adjacent first and second rows of a lead frame panel array, as well as other electronic devices undergoing concurrent fabrication processing in the lead frame panel array.

The method 200 begins with a starting lead frame panel array with conductive metal features (e.g., copper, aluminum, etc.) formed in rows R and columns C. FIG. 3 shows a portion of an example lead frame panel array 302, with a single, composite unit area 304 that includes two adjacent (e.g., first and second) rows RN−1 and RN in a first column CN along with portions of neighboring rows RN−2 and RN+1 and columns CN−1 and CN+1 in an array configuration. In this example, the example first row RN−1 of the column CN corresponds to the first portion P1 of the prospective electronic device 100 described above, and the second row RN of the column CN corresponds to the second portion P2 of the prospective electronic device 100 described above.

The method 200 in FIG. 2 includes die attach processing at 202, including attachment of the first and second (e.g., power) semiconductor dies 121 and 122. The die attach processing at 202 and other processing steps of the method 200 are shown in the drawings with respect to the illustrated unit area 304, and these processing steps can include similar processing in other unit areas of the lead frame panel array 302 that are not shown in the drawings.

FIG. 3 shows one example, in which a die attach process 300 is performed that attaches the first semiconductor die 121 to the first die attach pad 111 in the first row RN−1 of the column CN of the lead frame panel array 302. The die attach process 300 also attaches the second semiconductor die 122 to the second die attach pad 112 in the adjacent second row RN of the column CN of the lead frame panel array 302. The die attach process 300 can also include attaching other semiconductor dies in other unit areas (not shown) of the lead frame panel array, for example, by dispensing, printing, or otherwise providing solder and other electronic devices or conductive or nonconductive adhesive in select portions of top sides of certain lead frame features, as well as placement of semiconductor dies and corresponding locations on the solder paste or adhesive (e.g., using automated pick and place equipment, not shown), and subsequent solder reflow and/or curing processing (e.g., thermal reflow, thermal adhesive curing, UV adhesive curing, etc.) to adhere the semiconductor dies to the corresponding locations of the lead frame panel array.

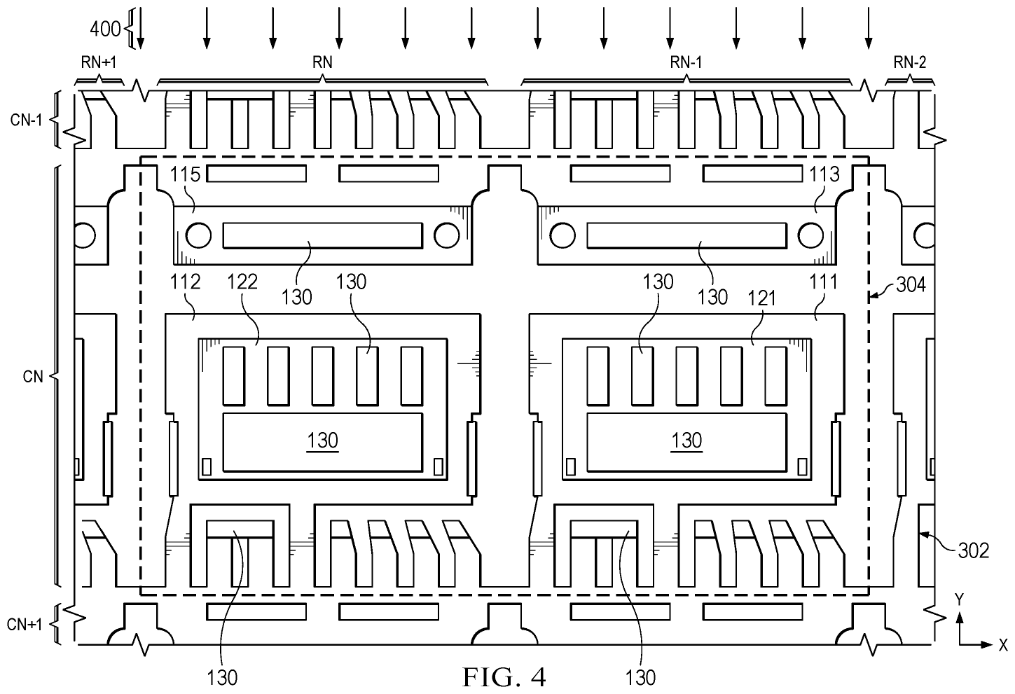

The method 200 continues at 204 in FIG. 2 with forming solder paste on select portions of the tops of the semiconductor dies 121 and 122 and on select portions of the top sides of other lead frame structures and the lead frame panel array 302. FIG. 4 shows one example, in which a solder paste formation process 400 is performed (e.g., dispensing, silk screening, printing, etc.) that forms solder paste 130 on select portions of the top sides of the semiconductor dies 121 and 122, as well as on portions of other lead frame features to facilitate subsequent electrical connection and mechanical attachment of metal clips in the illustrated unit area 304 of the lead frame panel array 302.

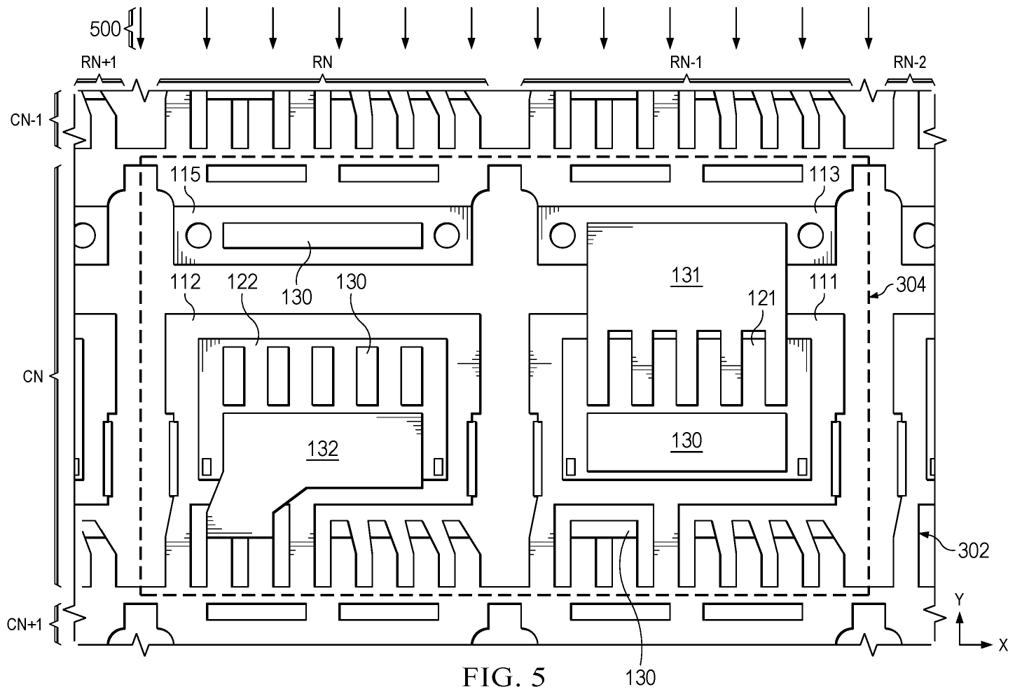

At 206 in FIG. 2, the method 200 optionally includes attaching the above described first and second metal clips for electrical interconnection of the high side drain and low side source connections of the half bridge circuit. In another example, such connections can alternatively be formed by wire bonding (not shown). FIG. 5 shows one example, in which a clip attachment process 500 is performed that attaches the first metal clip 131 to a corresponding portion of the solder 130 to form a mechanical and electrical connection between the first transistor drain lead frame portion 113 and conductive drain terminals on the top side of the first semiconductor die 121 to provide the first drain connection D1 to the conductive leads 114 along the lateral sixth side 106 of the prospective electronic device 100 being fabricated in the illustrated unit area 304.

The clip attachment process 500 in this example also attaches the second metal clip 132 by a corresponding portion of the solder 130 in order to mechanically and electrically connect a first pair of the conductive leads 109 of the second portion P2 to the conductive source terminals on the top side of the second semiconductor die 122 to provide the second source connection S2 along the lateral fifth side 105 of the prospective electronic device 100 as described above.

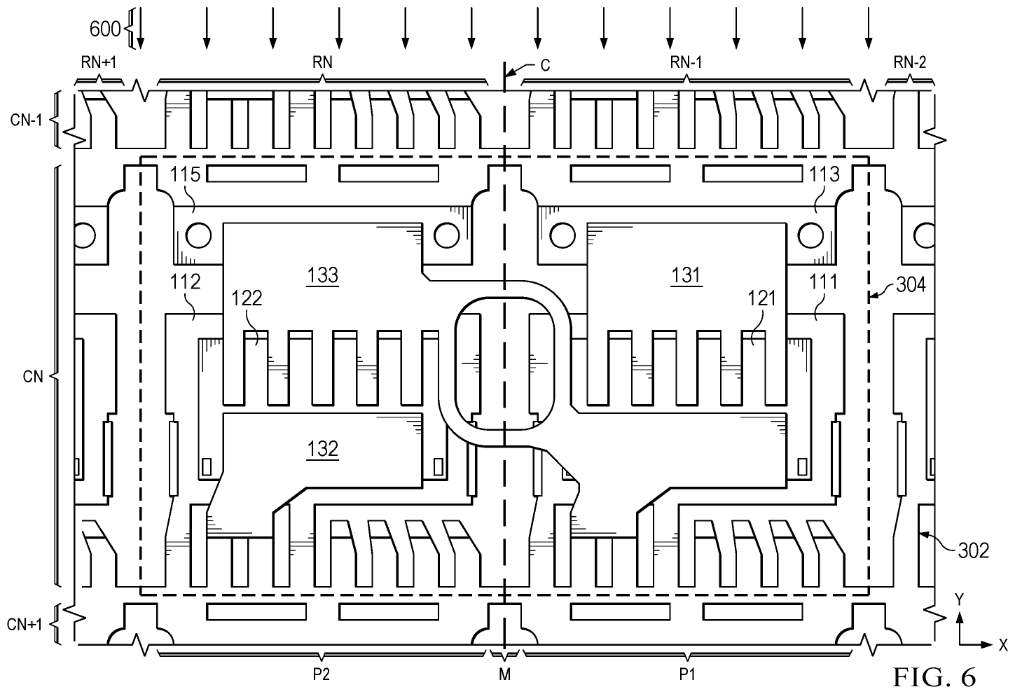

The clip attachment processing in this example also includes selectively attaching the switching node (e.g., third) conductive metal clip 133 at 208 in FIG. 2 in the illustrated prospective half bridge electronic device unit area 304 with the metal clip 133 extending in the first and second rows RN−1 and RN of the lead frame panel array 302. FIG. 6 shows one example, in which a clip attachment process 600 is performed, which can be a separate attachment process and/or a continuation of any included process 500 used in attachment of any included first and/or second metal clips 131, 132. The attachment process 600 in the illustrated example attaches the metal clip 133 within the first and second portions P1 and P2 and extending therebetween through the prospective middle portion M (e.g., FIGS. 1 and 1A above), with two separate branch portions that extend through the middle portion M2 encircle a perspective opening in a subsequently formed molded package structure 108.

The metal clip 133 is attached by corresponding portions of the solder 130 to electrically and mechanically connect or otherwise couple the first transistor electronic component Q1 of the first semiconductor die 121 to the second transistor electronic component Q2 of the second semiconductor die 122 to form a half bridge circuit switching node SW connected to the first source S1 of the first semiconductor die 121 in the first portion P1 (row RN−1) and to the second drain D2 of the second semiconductor die 122 in the second portion P2 (row N). The metal clip 133 in this example is also attached to corresponding portions of the solder 130 in order to mechanically and electrically connect the first source S1 to two of the conductive leads 109 along the fifth side 105 in the first portion P1 (row RN−1), as well as mechanical electrical connection of the second drain D2 to the second transistor drain lead frame portion 115 and the conductive leads 116 along the sixth side 106 in the second portion P2 (row N).

In certain implementations, such a clip 133 can be attached at 208 in FIG. 2 in other prospective half bridge electronic device unit areas of the lead frame panel array 302 and/or in two adjacent prospective single transistor electronic device unit areas of the lead frame panel array 302 (e.g., along two different adjacent rows of the illustrated column CN and/or of another column of the lead frame panel array 302, as illustrated and described below in connection with FIG. 14D).

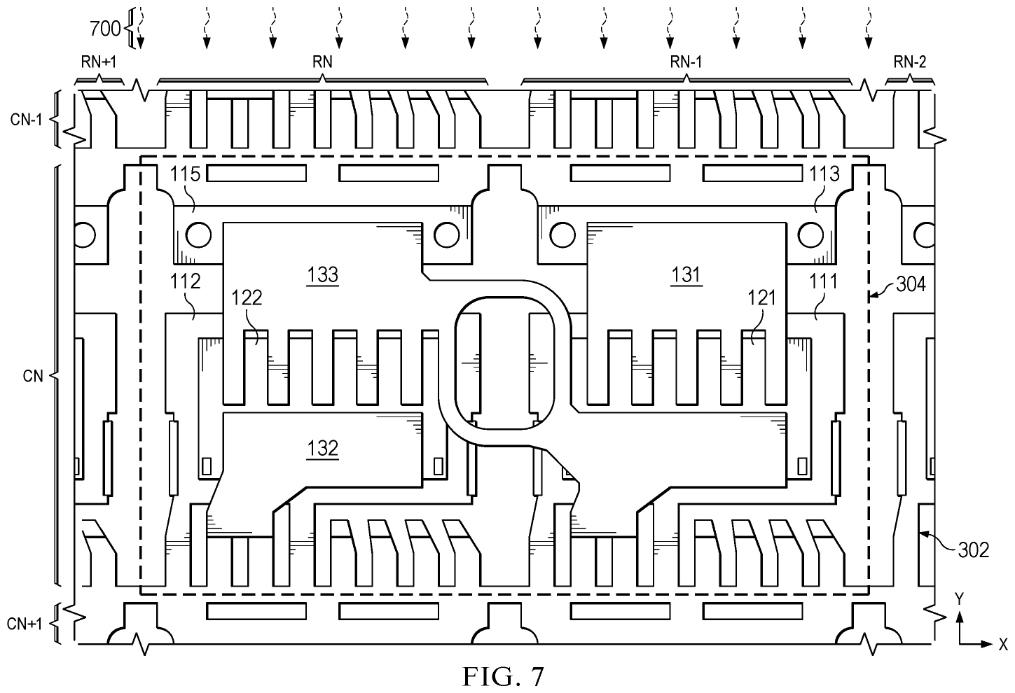

The method 200 continues at 210 in FIG. 2 with thermal processing to reflow the solder paste 130. FIG. 7 shows one example, in which a thermal reflow process 700 is performed that reflows the solder paste 130 to form the solder connections of the clips 131-133 by the corresponding solder 130 as described above in connection with FIGS. 1-1C.

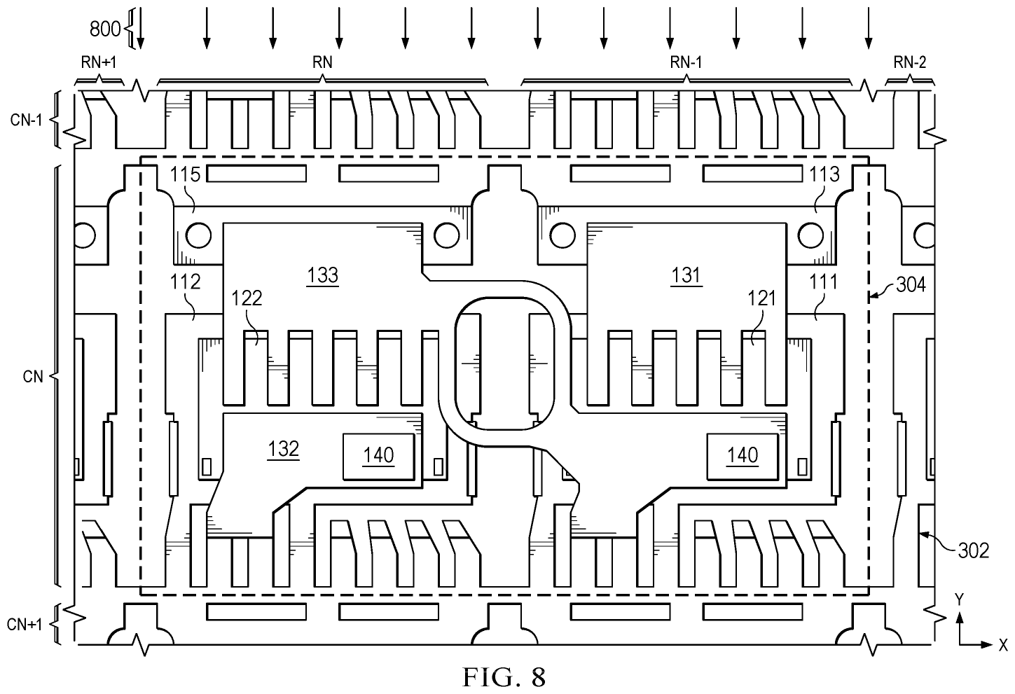

At 212 in FIG. 2, the method 200 in the illustrated example includes forming die attach film or adhesive on selected portions of the top sides of the second and third clips 132 and 133. FIG. 8 shows one example, in which a film formation process 800 is performed (e.g., dispensing, silk screening, printing, etc.) that forms the epoxy or other suitable adhesive 140 on corresponding portions of the clips 132 and 133. In another limitation, no driver dies or a single driver die are used in the prospective electronic device 100, and in the former case the film formation at 212 and subsequent driver die attachment at 214 in FIG. 2 can be omitted.

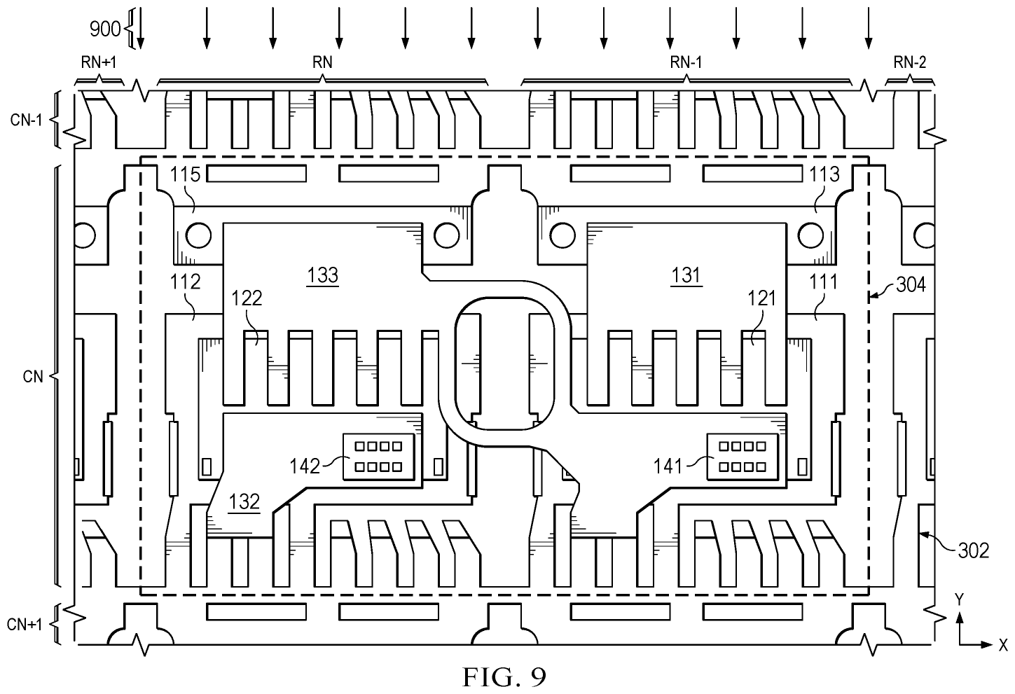

The illustrated example method 200 continues at 214 in FIG. 2 with driver die attachment. FIG. 9 shows one example, in which another die attach process 900 is performed (e.g., using automated pick and place equipment, not shown) that attaches the first and second driver dies 141 and 142 to the top sides of the respective clips 133 and 132.

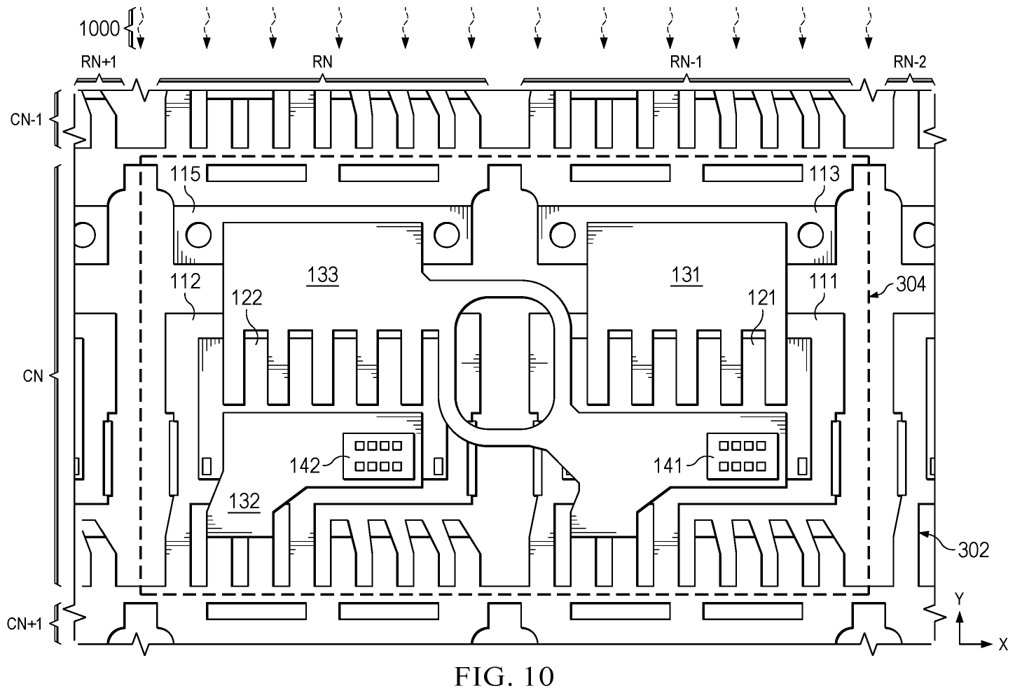

In the illustrated example, the method 200 continues at 216 in FIG. 2 with film curing. FIG. 10 shows one example, in which a curing process 1000 is performed that cures the adhesive 140 to secure the driver dies 141 and 142 to the respective clips 133 and 132, for example, by a thermal curing process 1000, a UV curing process 1000, etc.

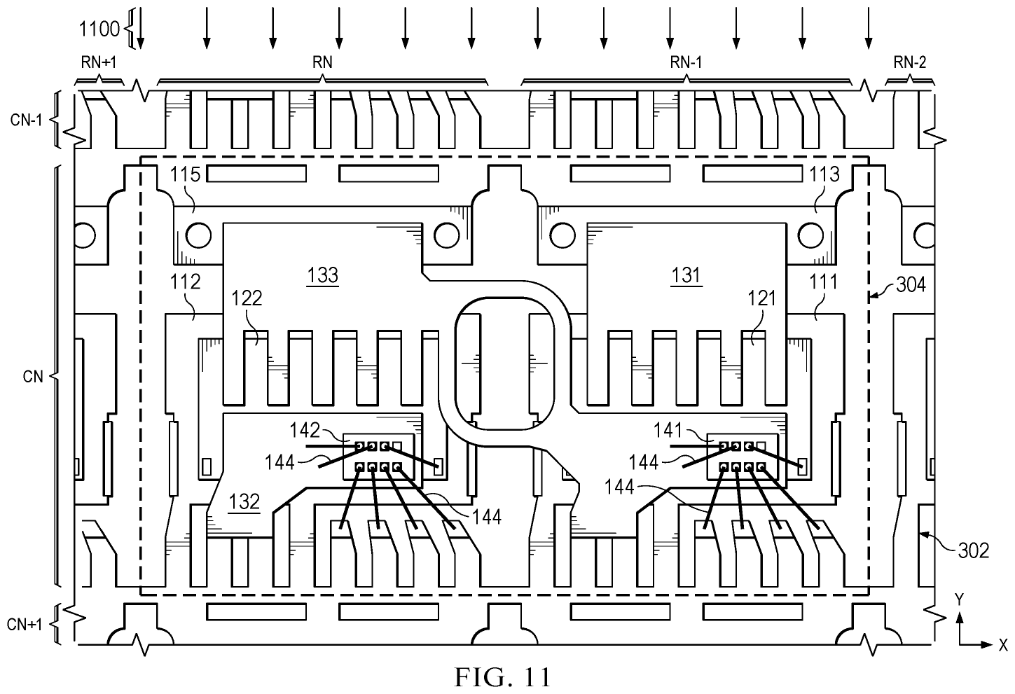

At 218 in FIG. 2, the method 200 in the illustrated example includes wire bonding. FIG. 11 shows one example, in which a wire bonding process 1100 is performed that creates the bond wires 144 for the electrical circuit connections of the driver dies 141 and 142 as discussed above. In another implementation, further and/or different bond wires (not shown) can be created at 218, for example, to provide connections between one or more transistor die terminals and corresponding leads in the unit area 304, such as in lieu of or in addition to the electrical connections provided by the illustrated first and second clips 131 and/or 132.

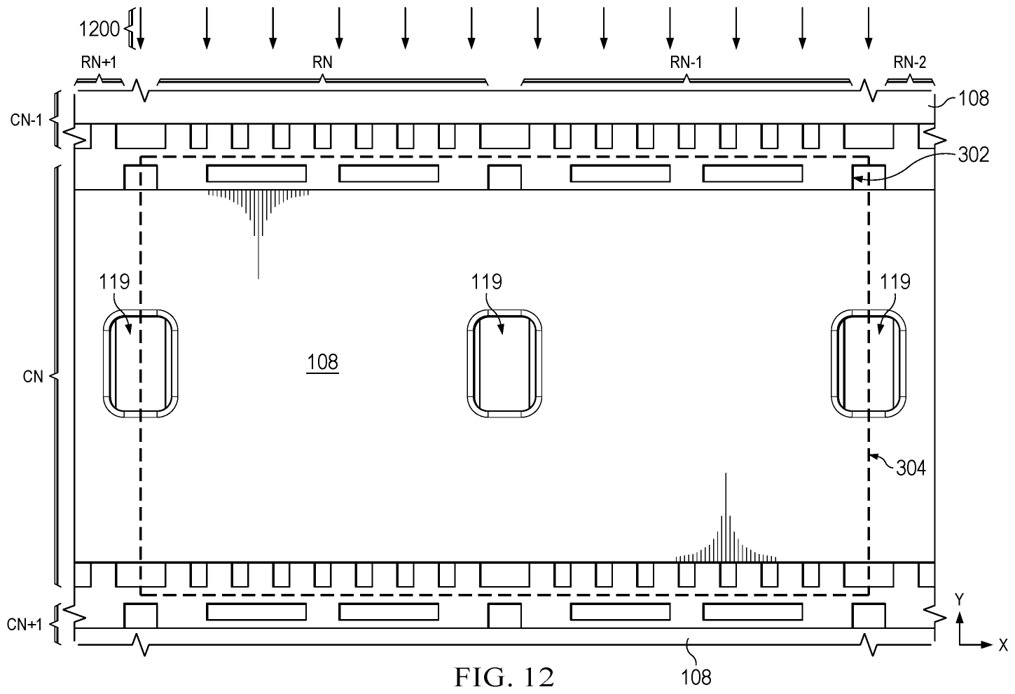

The method 200 continues at 220 in FIG. 2 with molding processing to form the molded package structure 108 along columns C of the lead frame panel array 302. FIG. 12 shows one example, in which a molding process 1200 is performed using a mold with downwardly extending features between adjacent columns and posts to form the above-described package structure openings 119 and/or indents 107.

In the illustrated example, the downwardly extending posts engage certain portions of the first and second die attach pads 111 and 112 in the illustrated unit area 304 and other die attach pad structures in other rows and columns of the lead frame panel array 302, for example, to allow proper flow of the molding compound 108 during mold filling operations such that the bottoms of the illustrated die attach pads 111 and 112 are not covered with molding material and will ultimately be exposed outside the bottom side 101 of the finished electronic device 100 (e.g., FIG. 1C above). FIG. 12 illustrates the described portion of the lead frame panel array 302 following removal of the upper mold structure, where the molding process 1200 creates openings 119 that expose portions of the conductive metal die attach pads 111 and 112.

In the illustrated example, moreover, the mold features to not engage the switching node clip 133, and the column length molded package structure 108 encloses the clip 133 in the illustrated unit area 304, although not a strict requirement of all possible implementations. The illustrated example forms the package structure 108 as a continuous molded structure that extends along the column CN and encloses the respective first and second semiconductor dies 121 and 122 as well as the metal clip 133.

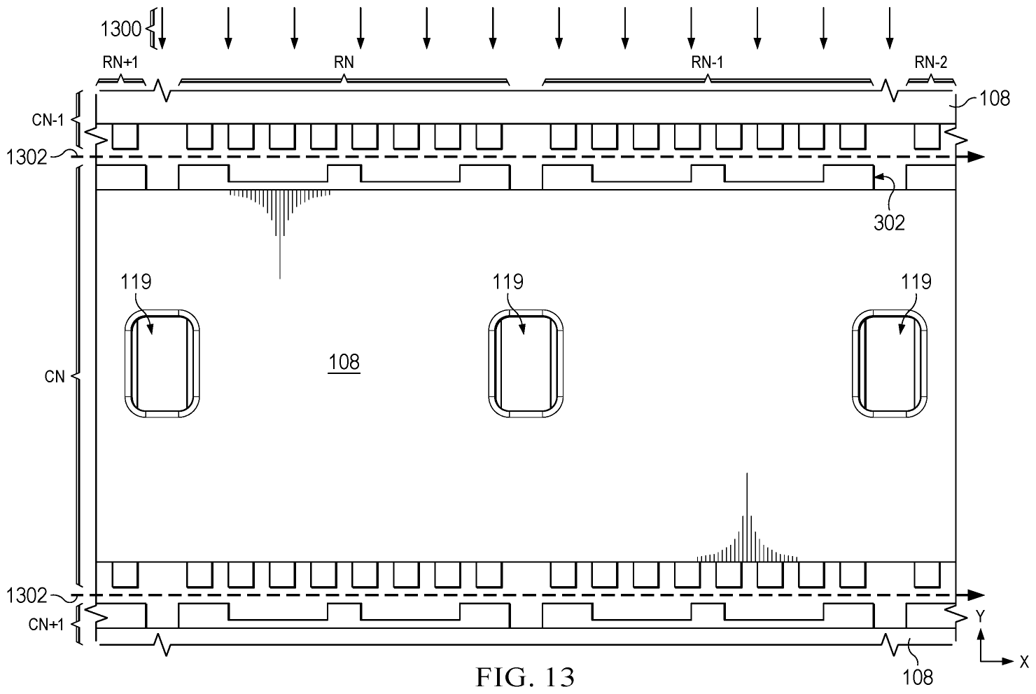

At 222 in FIG. 2, the method 200 continues with column direction lead trimming. In the illustrated example, the prospective electronic device 100 is a leadless structure, with the bottoms of the conductive leads 109, 114, and 116 being adapted for soldering to a host printed circuit board. In another example, other forms of leads and corresponding lead frame structures can be used, for instance, to form gullwing leads, J type leads, etc., and the processing at 222 can include both lead trimming and forming. FIG. 13 shows one example, in which the prospective leads of the lead frame panel array 302 are trimmed by a process 1300 (e.g., cut), for example, using saw cutting, laser cutting, chemical etching, or other suitable cutting or trimming processing, to separate the structures of the illustrated column CN from the adjacent or neighboring columns CN−1 and CN+1 along lines 1302. In the illustrated example, the process 1300 trims the conductive leads 109, 114, and 116 along respective longitudinal sides of the column CN of the lead frame panel array 302.

The method 200 continues at 224 with selective row direction package separation. Referring also to FIGS. 14-14D, FIG. 14 shows one example of suitable separation processing, in which a selective row direction cutting or separation process 1400 is performed (e.g., saw cutting, laser cutting, chemical etching, etc.) that cuts through the molded package structure 108 in certain selected portions along the lines 1402. As shown in FIG. 14, the process 1400 separates the packaged electronic device 100 from the lead frame panel array, and does not cut through the molded package structure 108 between the illustrated first and second rows RN−1 and RN, although this example shows cutting through the molded package structure between these rows RN−1 and RN in other columns of the lead frame panel array, such as the illustrated adjacent columns CN−1 and CN+1.

The separation process 1400 can be formed by automated and/or reconfigurable blade cutting equipment (not shown) that can selectively cut or not cut between designated pairs of adjacent rows in one or more of the columns of the lead frame panel array. As discussed below in connection with FIG. 14D, for example, insertion of a corresponding cutting blade between the rows RN−1 and RN can allow separation of two substantially equivalent single transistor electronic devices 1420, including cutting through the middle portion of the corresponding third clip 133. This selectivity allows cost effective selectable manufacturing of single transistor devices and/or composite half bridge electronic devices 100 for a given lead frame panel array processing sequence with little or no added cost or complexity.

FIG. 14A shows one implementation, in which the package separation at 224 includes selectively cutting a package structure 108 of another column CJ along lines 1402 between the respective first and second rows RN−1 and the RN. This separation processing example provides two adjacent single transistor electronic devices 1410 fabricated in the column CJ of the lead frame panel array. In this example, the individual electronic devices 1410 do not include any metal clips, and instead of bond wires 144 are used to form all the interconnections between the respective semiconductor dies and lead frame features. In this example, the row direction cutting process results in indents 107 along the lateral ends of the finished packaged electronic devices 1410 with no remaining package structure opening.

FIG. 14B shows two adjacent columns of the lead frame panel array after column direction lead trimming (e.g., after 222 in FIG. 2) and prior to row direction package separation (e.g., before 224 in FIG. 2). At this point in the processing, the column length molded package structures 108 of the lead frame panel array 302 have indents at the longitudinal ends thereof, and one or more openings (e.g., three in this example) between the ends and between adjacent rows of the array configuration.

FIG. 14C shows portions of the two adjacent columns of the lead frame panel array after selective row direction package separation (e.g., after 224 in FIG. 2), where the illustrated adjacent rows in one column provide a single instance of the above-described half bridge packaged electronic device or module 100, whereas the corresponding adjacent rows in the next column provide two instances of the single transistor packaged electronic device 1410 described above in connection with FIG. 14A.

FIG. 14D shows two further adjacent electronic devices in another column of the lead frame panel array after selective row direction package separation that cuts through a column molded package structure and a portion of an instance of the switching node clip 133 described above. In this example, the package separation at 224 in the method 200 of FIG. 2 can include selectively cutting 224 the metal clip 133 and the package structure 108 between the first and second rows RN−1, RN in the illustrated column CN for example, to provide a pair of electronic devices 1420 as shown in FIG. 14D. I

[symbol]

In each of the illustrated electronic devices 1420, the respective package structures 108 have opposite longitudinal ends 103 and 104 spaced apart from one another along the first direction X, and opposite lateral sides 105 and 106 spaced apart from one another along the second direction Y, as well as conductive leads 109 and 114 or 116 partially exposed outside the respective lateral sides 105 and 106 of the package structure 108. In this example, the first instance of the electronic device 1420 has an instance of the first semiconductor die 121, the second instance of the electronic device 1420 has an instance of the second semiconductor die 122, and these device instances have respective driver die instances 141 and 142. Following the row direction package separation (e.g., at 224 in FIG. 2), the individual electronic devices 1420 each have a metal clip 133 electrically coupled to an electronic component (e.g., transistor Q1 or transistor Q2) and the cut portion 1422 of the metal clip 133 between the lead frame panel array rows RN−1 and RN is exposed outside a first one of the longitudinal ends 103 and 104.

In the illustrated example, the metal clip 133 has a first cut portion 1422 exposed outside the first one of the longitudinal ends 103 and 104, and a second cut portion 1422 exposed outside the first one of the longitudinal ends 103 and 104. In this example, moreover, the individual package structures 108 of the respective devices 1420 each includes an indent 107 extending into the first one of the longitudinal ends 103 and 104, with the first and second cut portions 1422 of the metal clip 133 are spaced apart from the indent 107 and exposed outside the first one of longitudinal ends 103 and 104 on opposite sides of the indent 107.

Modifications are possible in the described examples, and other implementations are possible, within the scope of the claims.

What is claimed is:

1. An electronic device, comprising:
a package structure having opposite longitudinal ends spaced apart from one another along a first direction, opposite lateral sides spaced apart from one another along a second direction that is orthogonal to the first direction, a middle portion midway between the longitudinal ends, a first portion that extends between the middle portion and one of the longitudinal ends, and a second portion that extends between the middle portion and the other one of the longitudinal ends;
conductive leads partially exposed outside the respective lateral sides of the package structure;
first and second semiconductor dies having respective first and second electronic components; and
a metal clip that extends in the package structure from the first portion to the second portion through the middle portion and electrically couples the first electronic component of the first semiconductor die to the second electronic component of the second semiconductor die.

2. The electronic device of claim 1, wherein the package structure encloses the metal clip, the first and second semiconductor dies, and portions of the conductive leads.

3. The electronic device of claim 1, wherein the package structure has an opening that extends into the middle portion along a third direction that is orthogonal to the first and second directions.

4. The electronic device of claim 3, wherein the metal clip extends through the middle portion around two opposite sides of the opening.

5. The electronic device of claim 3, wherein:
the first semiconductor die is attached to a first die attach pad in the first portion;
the second semiconductor die is attached to a second die attach pad in the second portion; and
portions of the first and second die attach pads are exposed in the opening of the package structure.

6. The electronic device of claim 1, wherein:
the first electronic component of the first semiconductor die is a first transistor;
the second electronic component of the second semiconductor die is a second transistor; and
the metal clip electrically couples a source of the first transistor to a drain of the second transistor to form a switching node of a half bridge circuit.

7. An electronic device, comprising:
a package structure having opposite longitudinal ends spaced apart from one another along a first direction, and opposite lateral sides spaced apart from one another along a second direction that is orthogonal to the first direction;
conductive leads partially exposed outside the respective lateral sides of the package structure;
a semiconductor die having an electronic component; and
a metal clip electrically coupled to the electronic component and exposed outside a first one of the longitudinal ends.

8. The electronic device of claim 7, wherein the metal clip has a first portion exposed outside the first one of the longitudinal ends, and a second portion exposed outside the first one of the longitudinal ends.

9. The electronic device of claim 8, wherein:
the package structure includes an indent extending into the first one of the longitudinal ends; and
the first and second portions of the metal clip are spaced apart from the indent and are exposed outside the first one of longitudinal ends on opposite sides of the indent.

10. The electronic device of claim 7, wherein the electronic component is a transistor and the metal clip is electrically coupled to a source or drain of the transistor.

11. The electronic device of claim 7, wherein:
the package structure includes an indent extending into the first one of the longitudinal ends; and
the metal clip is spaced apart from the indent.

12. A system, comprising:
a circuit board; and
an electronic device attached to the circuit board and comprising:
a package structure having opposite longitudinal ends spaced apart from one another along a first direction, opposite lateral sides spaced apart from one another along a second direction that is orthogonal to the first direction, a middle portion midway between the longitudinal ends, a first portion that extends between the middle portion and one of the longitudinal ends, and a second portion that extends between the middle portion and the other one of the longitudinal ends;
conductive leads partially exposed outside the respective lateral sides of the package structure and soldered to conductive features of the circuit board;
first and second semiconductor dies having respective first and second electronic components; and
a metal clip that extends in the package structure from the first portion to the second portion through the middle portion and electrically couples the first electronic component of the first semiconductor die to the second electronic component of the second semiconductor die.

13. The system of claim 12, wherein the package structure has an opening that extends into the middle portion along a third direction that is orthogonal to the first and second directions.

14. The system of claim 13, wherein the metal clip extends through the middle portion around two opposite sides of the opening.

15. The system of claim 13, wherein:
the first semiconductor die is attached to a first die attach pad in the first portion;
the second semiconductor die is attached to a second die attach pad in the second portion; and
portions of the first and second die attach pads are exposed in the opening of the package structure.

16. The system of claim 12, wherein:
the first electronic component of the first semiconductor die is a first transistor;
the second electronic component of the second semiconductor die is a second transistor; and
the metal clip electrically couples a source of the first transistor to a drain of the second transistor to form a switching node of a half bridge circuit.

17. A method of fabricating an electronic device, the method comprising:
attaching a first semiconductor die to a first die attach pad in a first row of a column of a lead frame panel array;
attaching a second semiconductor die to a second die attach pad in an adjacent second row of the column of the lead frame panel array;
attaching a metal clip to the first and second semiconductor dies with the metal clip extending in the first and second rows;
forming a package structure that extends along the column and encloses the first and second semiconductor dies and the metal clip;
trimming conductive leads along longitudinal sides of the column of the lead frame panel array; and
separating the electronic device from the lead frame panel array.

18. The method of claim 17, wherein separating the electronic device from the lead frame panel array includes selectively cutting the package structure along lateral ends of the respective first and second rows in the column.

19. The method of claim 18, wherein separating the electronic device from the lead frame panel array further includes selectively cutting a package structure of another column between the respective first and second rows.

20. The method of claim 17, wherein separating the electronic device from the lead frame panel array includes selectively cutting the metal clip and the package structure between the first and second rows in the column.
